(19) United States
(12) Patent Application Publication
(10) Pub. No.: US 2025/0004081 A1
(43) Pub. Date: Jan. 2, 2025

(54) METHOD FOR ACQUIRING A MAGNETIC RESONANCE IMAGE DATASET

(71) Applicants: Siemens Healthineers AG, Forchheim (DE); The General Hospital Corporation, Boston, MA (US)

(72) Inventors: Daniel Polak, Erlangen (DE); Daniel Nicolas Splitthoff, Uttenreuth (DE); Stephen Farman Cauley, Winchester, MA (US); Thorsten Feiweier, Poxdorf (DE); Lawrence L. Wald, Cambridge, MA (US)

(21) Appl. No.: 18/759,265

(22) Filed: Jun. 28, 2024

(30) Foreign Application Priority Data
Jun. 28, 2023 (EP) 23182026.7

(51) Int. Cl. G01R 33/48; G01R 33/54; G01R 33/56; G01R 33/561

(52) U.S. Cl. CPC G01R 33/4818; G01R 33/543; G01R 33/5608; G01R 33/5613; G01R 33/5616

(57) ABSTRACT

A method for acquiring a magnetic resonance image dataset of a field-of-view using an imaging protocol includes acquiring a low-resolution scout image dataset of the field-of-view, and sets of one or more additional k-space lines within a central region of k-space at regular intervals during the imaging protocol. A contrast of the low-resolution scout image dataset and a contrast of the sets of one or more additional k-space lines are matched and are independent of a contrast of the magnetic resonance image dataset. The low-resolution scout image dataset and the sets of one or more additional k-space lines are acquired after an at least approximately matched magnetization preparation and matched recovery times.

This application claims the benefit of European Patent Application No. EP 23182026.7, filed on Jun. 28, 2023, which is hereby incorporated by reference in its entirety.

### BACKGROUND

The present embodiments relate to acquiring a magnetic resonance image dataset.

Independent of the grammatical term usage, individuals with male, female, or other gender identities are included within the term.

Patient motion is one of the most common and costly of artifacts in Magnetic Resonance Imaging (MRI) and may seriously degrade the diagnostic quality of magnetic resonance (MR) exams.

Fast imaging protocols reduce the impact of motion. For example, parallel imaging techniques, as summarized in J. Hamilton, D. Franson, and N. Seiberlich “Recent Advances in Parallel Imaging for MRI,” Prog. Nucl. Magn. Reson. Spectrosc., vol. 101, pp. 71-95, 2017, exploit the properties of modern multi-channel coil arrays to separate aliased pixels in the image domain or to estimate missing k-space data, using knowledge of nearby acquired k-space points, in order to allow scan time reduction by sampling a smaller number of phase encoding lines in k-space.

Some magnetic resonance imaging (MRI) motion correction techniques involve measuring the motion by tracking devices or navigator acquisitions.

By contrast, retrospective methods correct for motion artefacts after the data acquisition without disruptions to the sequence timing or inclusion of additional hardware. By including motion parameters into the MR forward model, these techniques account for the motion of the patient in the final image reconstruction and therefore reduce motion artefacts. In some techniques, the motion data may be derived from the acquired k-space data itself. For multi-shot acquisitions, the goal in retrospective motion correction techniques is to extract the per shot motion parameters and the motion-free image simultaneously. This may be accomplished by either minimizing an image quality metric, such as image entropy, or by minimizing the data consistency error of a parallel “imaging+motion” forward model, as described in L. Cordero-Grande, E. J. Hughes, J. Hutter, A. N. Price, and J. V Hajnal, “Three-dimensional motion corrected sensitivity encoding reconstruction for multi-shot multi-slice MRI: Application to neonatal brain imaging,” Magn. Reson. Med., vol. 79, no. 3, pp. 1365-1376, 2018, L. Cordero-Grande, R. Teixeira, E. Hughes, J. Hutter, A. Price, Hajnal, “Sensitivity Encoding for Aligned Multishot Magnetic Resonance Reconstruction,” IEEE Trans. Comput. Imaging, vol. 2, no. 3, pp. 266-280, 2016 and M. W. Haskell, S. F. Cauley, and L. L. Wald, “TArgeted Motion Estimation and Reduction (TAMER): Data consistency based motion mitigation for MRI using a reduced model joint optimization,” IEEE Trans. Med. Imaging, vol. 37, no. 5, pp. 1253-1265, 2018. For the latter, the motion and image vector are jointly estimated via an inversion of the non-linear forward model. This corresponds to a large-scale non-linear optimization problem that is typically computationally very expensive. Previously proposed methods alternate between optimizing just the image or the motion parameters while assuming the other to be fixed (see L. Cordero-Grande in Magn. Reson. Med.), instead of updating all optimization variables at once. Nevertheless, repeated updates of the imaging voxels lead to excessive computation that prohibits its use in clinical settings.

When the “imaging+motion” model and the underlying imaging protocol also include parallel imaging techniques that make use of the complex sensitivity profiles of multi-channel coil arrays, such as Sensitivity encoding (SENSE) or array coil spatial sensitivity encoding (ASSET), it is referred to as “SENSE+motion” model.

In “Scout accelerated motion estimation and reduction (SAMER)”, Magn. Reson. Med., vol. 87, pp. 163-178, 2022, https://doi.org/10.1002/mrm.28971, D. Polak, D. N. Splitthoff, B. Clifford, W.-C. Lo, S. Huang, J. Conklin, L. L. Wald, K. Setsompop and S. Cauley propose a technique that utilizes a single rapid scout scan to drastically reduce the computational cost of motion estimation. The scout image contains center of k-space information that is compared against the k-space data of the actual MR acquisition for each shot, to derive the motion of the subject. This corresponds to registration of the k-space data with the scout image in k-space. This strategy is used to completely avoid the alternating optimization of subject motion and image volume, which is otherwise required in retrospective motion correction techniques. In the SAMER-technique, a motion trajectory of the subject is first estimated, and the motion trajectory is then used in a motion-aware parallel image reconstruction, using, for example, a “SENSE+motion” forward model, to yield the motion-mitigated image. This reduces the computational costs by a number of orders of magnitude (e.g., several orders of magnitude) when compared to established alternating optimization methods.

In D. Polak, J. Hossbach, D. N. Splitthoff et al. “Motion guidance lines for robust data consistency-based retrospective motion correction in 2D and 3D MRI”, Magn. Reson. Med. 2023:1-14, doi: 10.1002/mrm.29534, D. Polak et al. have extended the SAMER method to include the repeated acquisition of a small number of motion guidance lines in each shot, which are used for motion estimation by being compared with the data from the scout scan. This allows for very rapid and fully separable estimation of motion parameters shot-by-shot.

However, the SAMER method using additional motion guidance lines has some disadvantages that make it not equally well suitable to all types of imaging protocols. For example, the method requires the low-resolution scout scan to be acquired very rapidly, so that the low-resolution scout scan may be assumed to be motion-free. In a three-dimensional (3D) imaging sequence, this may be achieved using a single shot of data acquisition, having, for example, a scan time of about 1 second in a 3D magnetization prepared rapid acquisition with gradient echoes (MPRAGE) sequence. In a two-dimensional (2D) scan, in which a stack of 2D images (also referred to as “slices”) is acquired in one imaging protocol, the acquisition time for the corresponding 2D low-resolution scout image dataset including a stack of 2D images may be much longer: While a single slice of the 2D scout may be acquired in just a single echo train (e.g., in about 100-200 ms), a full stack of N slices (e.g., N=20-30) will take several seconds (e.g., 6 seconds in T2 TSE (Turbo Spin-Echo)). Hence, the scout scan may no longer be considered motion-free, which is a pre-requisite for SAMER. This problem is even worse in sequences using concatenations such as T2 FLAIR TSE (FLuid Attenuated Inversion Recovery), in which, for example, all of k-space from odd slice numbers is acquired in the first half of the scan, while even slice numbers are sampled in the second half, or the other way around. As the scout slices are always acquired in the first echo train of each concatenation, the acquisition of odd and even scout slices are now separated by up to 1-2 minutes. This dramatically increases the risk of motion in the scout data.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, these problems of the SAMER method, such as the problem of long acquisition times of the low-resolution scout scan, may be overcome. As another example, a method for acquiring MR image datasets for retrospective motion correction, which may be applied to all types of imaging protocols, independent of their contrast and type (e.g., gradient echo, spin echo, inversion recovery, etc.) is provided.

In an embodiment, a method for acquiring a magnetic resonance image dataset of a field-of-view includes using an imaging protocol in which spatial encoding is performed using phase encoding gradients along at least one phase encoding direction, and frequency encoding gradients along a frequency encoding direction. k-space is sampled during the imaging protocol in a plurality of k-space lines oriented along the frequency encoding direction, and having different positions in the at least one phase encoding direction. The method includes acquiring a low-resolution scout image dataset of the field-of-view. The method also includes acquiring sets of one or more additional k-space lines within a central region of k-space at at least approximately regular intervals during the imaging protocol. The method is characterized in that the contrast of the low-resolution scout image dataset and the contrast of the additional k-space lines are at least approximately matched and are, for example, independent of the contrast of the magnetic resonance image dataset. In some embodiments, the contrast of the low-resolution scout image dataset and the contrast of the additional k-space lines are different to the contrast of the magnetic resonance image dataset.

The present embodiments have recognized that some amendments are required to the method proposed by D. Polak in Magn. Reson. Med. 2023:1-14, doi: 10.1002/mrm.29534 in order for the method to be broadly applicable to different types of imaging protocols and protocol settings. For example, the retrospective motion correction using a small number of additional k-space lines, which are herein also referred to as “motion guidance lines” or “guidance lines”, is greatly facilitated if the contrast of the low-resolution scout image dataset (hereinafter also referred to as “scout” or “scout image”) has a similar or, for example, the same contrast as the motion guidance lines. “Contrast” in the context of this application may provide that the contrast imparted on the MR data by the specific acquisition timing (e.g., TR (repetition time), TE (echo time), or TI (Inversion Time)), as well as any magnetization preparation and other factors that influence which types of tissues appear dark and which appear bright in the MR image dataset. The present embodiments have recognized that, in order to be able to use only a few motion guidance lines to estimate motion parameters of the subject and thereby reconstruct a motion-corrected image dataset, it is to be provided that the additional k-space lines and the scout image have at least similar contrast. Therefore, the present embodiments provide to match the contrast of the low-resolution scout image dataset and the contrast of the additional k-space lines. This may be achieved by designing the acquisition of the scout and/or the motion guidance lines such that their contrast is at least approximately equal, independent of the desired contrast of the imaging protocol used for the acquisition of the motion-corrected image dataset. For example, the contrast of the scout image may be adapted to match the contrast of the motion guidance lines, or vice versa. “At least approximately matched” may provide that the contrast is matched to within ±15%, within ±10%, or within ±5%.

In embodiments, the additional k-space lines are no longer fully integrated into the imaging protocol (e.g., into an echo train), but are present as a separate entity. Thereby, the same acquisition module (e.g., the acts of the method concerning the acquisition of the scout image and the additional k-space lines) may be used for different types of imaging sequences (e.g., for spin-echo (SE), turbo spin-echo (TSE), gradient echo, or inversion recovery (IR) sequences with different contrasts, such as T1-weighted, T2-weighted, spin-density, FLAIR etc.) and independent of the sequence settings, such as resolution, bandwidth, echo time (TE), etc. In embodiments, the type of imaging sequence and the sequence settings used for the scout image and the motion guidance lines are selected independently from the type of imaging sequence used for the acquisition of the image dataset (e.g., in the imaging protocol). In many useful embodiments, the type of imaging sequence and/or the sequence settings used for the scout image and the motion guidance lines are different to those used for the acquisition of the image dataset. For example, if the imaging sequence used in the imaging protocol is a spin echo sequence, the scout image and the motion guidance lines may be acquired using a gradient echo type sequence. In one embodiment, the scout image and the motion guidance lines are acquired using the same type of imaging sequence and similar or identical sequence settings. Thus, the acquisition of the image dataset and the acquisition of the scout image and the guidance lines are completely decoupled in the sense that they may have different contrasts and use different sequence timings. This makes the approach of the present embodiments very flexible and easy to integrate into different types of image protocols.

In addition, the present embodiments have minimal impact on the image quality and contrast, which leads to minimal disruption of the sequence timing of the imaging protocol, and may be simply integrated into any type of imaging protocol/sequence. This also leads to minimal increases in radiofrequency (RF) stimulation and specific absorption rate (SAR).

The method of the present embodiments may be executed on any medical or other MRI apparatus. The field-of-view includes a body part of a subject, which may be human or animal (e.g., a patient to be examined). The image dataset is, for example, acquired from a part of the body that is subject to undesired motion (e.g., the head or neck, a limb such as a leg, arm, knee, hand, or a part subjected to breathing motion such as the thorax or abdomen). The image dataset may be a 3D dataset, acquired using two phase encoding directions, or the image dataset may be a 2D image dataset. A 2D image dataset includes one or a stack of 2D slices. A 2D image dataset is acquired using a slice selection gradient typically followed by phase encoding in one in-plane direction and frequency encoding in the other in-plane direction.

The imaging protocol may use any type of imaging sequence (e.g., a spin-echo or gradient echo sequence). The method of the present embodiments is particularly suited to TSE or TSE-type sequences (e.g., having T1-weighted, T2-weighted, or other contrast). The imaging sequence may be a non-steady-state sequence (e.g., one in which the signal intensity or contrast varies over an echo train due to T1 and/or T2 relaxation, such as magnetization prepared rapid gradient echo imaging (MPRAGE) or TSE. The imaging sequence may also be an imaging protocol in which two images are acquired shortly one after the other after the same preparation pulse with different contrasts, such as MP2RAGE. Further examples of the imaging protocol are a sampling perfection with application optimized contrast using different flip angle evolution (SPACE) sequence and fluid-attenuated inversion recovery (FLAIR) sequence, but other types of imaging sequences are also possible.

The thereby acquired magnetic resonance image dataset, also referred to as “image dataset,” “image,” or “high-resolution image,” is designed to be reconstructed using retrospective motion correction techniques (e.g., the technique disclosed by D. Polak et al. in Magn. Reson. Med., vol. 87, pp. 163-178, 2022 and Magn. Reson. Med. 2023:1-14, doi: 10.1002/mrm.29534). The image dataset may be acquired for diagnostic purposes and thus may have a high spatial resolution of, for example, an in-plane resolution of 0.3 mm-3 mm or 0.4-2 mm. The voxel size may be, for example, 0.5 to 12 mm³ or 2 to 8 mm³. For a 2D image, the in-plane resolution may, for example, be 0.3 mm-2 mm (e.g., 0.4-1.2 mm).

The low-resolution scout image may cover the same field-of-view as the magnetic resonance image dataset. Thus, in case of a 3D image, the low-resolution scout image covers the same volume. In case the image dataset is a stack of 2D slices, the scout image includes also a stack of low-resolution 2D slices. However, it is possible that the low-resolution scout includes fewer slices than the high-resolution image (e.g., only every second or third slice). The low-resolution scout image may have a spatial resolution of 2-8 mm or 3-5 mm (e.g., 4 mm) in the phase-encoding direction(s). In one embodiment, the acquisition of the scout is very rapid, requiring, for example, 1-5 seconds (e.g., 1-2 seconds). The scout may be acquired once before or after the imaging protocol (e.g., before).

Thus, the acquisition of the low-resolution scout may be the first method act, though the acquisition of the low-resolution scout may also be the last and may, in principle, also be performed in the middle of the imaging protocol. In a further act, the imaging protocol is carried out. Before executing the method of the present embodiments, an MR examination will often include some preparatory scans. For example, SENSE+motion reconstructions require a coil sensitivity map that may be computed from a separate, very rapid referenced scan. This scan is often the first scan of the acquisition, followed by the low-resolution scout and the imaging scan/protocol. However, this order may be changed as desired.

The sets of additional k-space lines are acquired in a central region of k-space, where the central region may be covered by the low-resolution scout image. However, each set of additional k-space lines may include fewer k-space lines than would be required to reconstruct a scout image. For example, a set of k-space lines may include 1 to 8 or 1-4 k-space lines for each 2D slice of a 2D image dataset. In case the image dataset is a 3D image dataset, a set of k-space lines may include 2 to 32 (e.g., 3-8) k-space lines. The set of additional k-space lines is acquired repeatedly during the imaging protocol (e.g., at at least approximately regular intervals). “At least approximately,” when used in this application, may be within ±15%, within ±10%, or within ±5%. Each set of additional k-space lines is intended to provide information on the position of the subject at the point in time at which the set was acquired, also referred to as motion state herein. Therefore, the intervals in which the sets are acquired may be set to a time that gives a sufficiently high temporal resolution and does not take up too much of the total scan time. The interval at which the sets of additional k-space lines are acquired may be between 100 ms and 3000 ms or between 5000 ms and 1500 ms. In 3D imaging protocols, one set of guidance lines may be acquired per TR (e.g., every 1-3 seconds). In 2D imaging protocols, guidance lines may be acquired in every slice (e.g., every 80-250 ms); however, to estimate one motion state, guidance line information from multiple slices is to be combined to obtain through-plane information. Hence, the temporal resolution in 2D may also be in the 1-2 second range.

“Additional” may be that the k-space lines are acquired in addition to those that are required under the imaging protocol to acquire the MR image (e.g., the k-space lines are redundant when it comes to image reconstruction). The sets of additional k-space lines may be at the same position in k-space at each acquisition, but this is not mandatory.

According to an embodiment, the imaging protocol includes a plurality of echo trains, one or more k-space lines being acquired in one echo train. An “echo train,”, also referred to as “shot,” includes a plurality of magnetic resonance (MR) echoes (e.g., spin echoes and/or gradient echoes). During each echo, a k-space line is acquired. In most sequences, an echo train includes an excitation or preparation pulse, and then all echoes have their own excitation/refocusing pulses. For example, MPRAGE typically has a 180° preparation pulse followed by multiple excitation pulses of around 10°. TSE imaging protocols typically use a 90° excitation pulse followed by multiple 180° refocusing pulse. There may be 1 to 512 echoes or 8 to 256 echoes in one echo train. In 2D TSE sequences, an echo train may contain less than 40 or less than 30 echoes. In one embodiment, one set of additional k-space lines is acquired before or after at least some (e.g., more than 80%) of the echo trains (e.g., using low flip angle excitation pulses). There may be as few as one echo per echo train (e.g., in T1-weighted TSE).

According to an embodiment, the low-resolution scout image dataset and the additional k-space lines are acquired after an at least approximately matched magnetization preparation. Thereby, it is possible to also match the contrast at least approximately. Magnetization preparation may, for example, provide that, before the excitation pulses, the spins are in a defined spin state (e.g., the spins are saturated or inverted). According to this embodiment, the spin state before the acquisition of the scout image and before each set of guidance lines is at least approximately the same. For example, the magnetization preparation may involve a saturation, followed by a defined recovery time or wait time, after which the respective MR data is acquired. The magnetization preparation may be achieved by a specific magnetization preparation module (e.g., a saturation module) that includes a saturation RF pulse followed by gradient spoiling. Alternatively, the magnetization preparation may be achieved by the imaging protocol itself. For example, at the end of a TSE echo train, the magnetization typically is saturated (e.g., the longitudinal magnetization is negligible). Thus, in order to achieve a matched magnetization preparation, the scout image may be acquired after a saturation preparation module, and the motion guidance lines may be acquired directly after a TSE echo train. Thereby, very similar contrast may be achieved.

According to an embodiment, the low-resolution scout scan and/or the additional k-space lines are acquired using low flip angle excitation pulses. In one embodiment, they are acquired using a fast low angle shot (FLASH) type acquisition. FLASH is a gradient echo sequence that combines a low flip angle radio-frequency excitation with a short repetition time. Depending on the desired contrast, the FLASH technique includes spoiled versions, in which coherences in the transverse magnetization are deliberately destroyed (e.g., using gradient spoilers) and that provide T1-weighted contrast. For providing T2 or T2/T1-weighted contrast, it is possible to incorporate transverse coherences into the steady-state signal by refocusing the magnetization, either by using a constant phase per repetition, or by using zero phase per repetition, resulting in a fully balanced steady state. Because of its versatility in reaching different kinds of contrast, FLASH is advantageous for acquiring the low-resolution scout and/or the guidance lines. Further, the flip angle may be set to such a low value that there are minimal contrast changes of the imaging scan. Any RF excitation (e.g., in addition to what is prescribed by the imaging protocol) will change the spin evolution; however, if very small flip angles are selected (e.g., <) 5°, the effect will be negligible. According to an embodiment, the low-angle excitation pulses of the low-resolution scout and/or the additional k-space lines have an excitation angle of 1°-30°, 3°-20°, or 3°-10°.

In an embodiment, both scout and motion guidance lines are acquired using low flip angle excitation pulses (e.g., FLASH). FLASH guidance lines are advantageous because of their versatility and because they may be integrated into any type of imaging protocol. For example, a set of FLASH guidance lines may be acquired after each echo train (e.g., TSE echo train).

According to an embodiment, the imaging protocol is a turbo spin-echo sequence, where each echo train includes a plurality of spin echoes, one k-space line being acquired during each spin echo. The turbo factor (e.g., the number of spin echoes per echo train) may be between 2 and 200 or 2 to 40. A TSE sequence is advantageous because each TSE echo train, independent of the type of contrast (T1, T2, FLAIR), will lead to the same spin state at the end (e.g., negligible longitudinal magnetization after the echo train). The imaging protocol may also be a spin-echo sequence having one spin echo per echo train. In one embodiment, a set of one or more motion guidance lines is acquired a pre-determined recovery time after the last spin echo of some or all of the echo trains, resulting in a T1-weighted contrast of the guidance lines.

According to an embodiment, the low-resolution scout image dataset is acquired using one or more saturation preparation modules, where each saturation preparation module is followed by a readout of one or more k-space lines (e.g., after a pre-determined recovery time). Thereby, the contrast of the low-resolution scout image dataset may be designed to match that of motion guidance lines, if they are acquired at the end of a TSE echo train, as explained above. The saturation preparation module may include a saturation RF pulse (e.g., a 90° pules) followed by a gradient spoiler. After the pre-determined recovery time, the saturation preparation module is followed by an acquisition of several (e.g., 2 to 16 or 4 to 8) k-space lines (e.g., by readouts with low flip angle excitation and spatial encoding gradients).

In an implementation of this embodiment, the additional k-space lines of the low-resolution scout image dataset are acquired a pre-determined first recovery time after a saturation preparation module, and the additional k-space lines are acquired a pre-determined second recovery time after the end of an echo train (e.g., a TSE train), which may be followed by a gradient spoiler. The first recovery time and the second recovery time are equal within ±20%, within ±10%, or within ±5%. Thereby, the contrast of the scout image and the additional k-space lines are matched sufficiently, so that the additional k-space lines may be used in the SAMER motion correction algorithm.

In both the acquisition of the low-resolution scout and the additional k-space lines, spoiler gradients or modules may be used and adapted to suppress undesired coherences in the magnetization.

According to an embodiment, the imaging protocol is a two-dimensional imaging protocol, in which a stack of two-dimensional slices is acquired. Thus, the MR image dataset includes a stack of 2D images of slices. In this embodiment, the imaging protocol may be a TSE sequence. This embodiment is advantageous because the low-resolution scout is also acquired as a set of 2D slices, and this would in the prior art method either considerably lengthen the acquisition time or would lead to mismatched contrast between the scout and the guidance lines. If, however, the motion guidance lines are not acquired as part of the echo train of the imaging protocol, as in the prior art methods, but are, for example, acquired with a FLASH-type excitation, their contrast may be matched to that of the scout.

2D acquisition provides the further advantage that a slice inter-leaving scheme may be used to best exploit the recovery time (e.g., where used) and improve scan efficiency. According to an embodiment, the additional k-space lines relating to one slice are acquired directly after an echo train in which k-space lines of another slice were acquired in order to increase the second recovery time to the pre-determined value. In other words, the motion guidance lines for one slice are not acquired directly after an echo train from that same slice, but after the echo train from another slice. The order in which the guidance lines are acquired from the different slices may be arranged such that each set of guidance lines is acquired a pre-determined second recovery time after the end of an echo train from that slice. For example, one or two echo trains from other slices may be interspersed. It is, for example, favorable to choose a slice ordering scheme that reduces overlap/crosstalk between the slices excited during one recovery time (e.g., the slices should not be adjacent).

An alternative way of achieving the desired TI2 time is inserting an additional wait time between the end of an echo train from a specific slice and the acquisition of guidance lines from the same slice.

Also, both methods (e.g., slice inter-leaving and inserting wait time) may be combined.

A similar acquisition scheme may be applied in the acquisition of the 2D low-resolution scout images: First, the saturation modules may be played for a plurality of slices, and then, after the pre-determined first recovery time for each slice, k-space lines of the plurality of slices are acquired (e.g., using low flip angle excitation). Again, a slice interleaving scheme may be chosen to reduce cross-talk between the slices.

According to an embodiment, the saturation preparation module(s) used in the scout acquisition may include magnetization transfer (MT) preparation pulses that are adapted to match the contrast of the low-resolution scout image dataset to the contrast of the additional k-space lines. By such magnetization transfer pulses, RF energy may be applied exclusively to the pool of bound water. Some of this energy is then transferred to the free water pool. Thereby, the contrast may be tuned to the desired contrast. For example, the number of MT-pulses per time or their amplitude may be modified to match the contrast of the motion guidance lines. Further, in 2D imaging protocols, the MT preparation pulses may be continued between the slice acquisition of the scout to maintain the desired contrast.

According to an embodiment, in the acquisition of the 2D low-resolution scout image dataset, the saturation preparation module uses a saturation pulse that has a higher slice thickness than the low-angle excitation pulses. Thereby, a more homogenous saturation of the slices may be achieved. In one embodiment, the slice ordering scheme is adjusted in order to avoid spin history/slice cross talk effects, especially when choosing increased slice thickness for the saturation.

According to an embodiment, in the acquisition of the 2D or 3D low-resolution scout image dataset, the saturation preparation module may use adiabatic RF pulses. Adiabatic pulses are relatively insensitive to B1 inhomogeneity and frequency offset effects, and therefore provide a homogenous saturation of the field-of-view.

According to an embodiment, in the acquisition of the 2D or 3D low-resolution scout image dataset, additional contrast preparation modules may be used in order to match the contrast of the scout to the motion guidance lines. For example, fat suppression or water excitation modules/pulses may be used.

According to an embodiment, flow attenuation pulses applied outside of the field-of-view are used during the acquisition of the low-resolution scout image dataset. Thereby, the signal from inflowing spins is reduced.

According to an embodiment, the imaging protocol includes regional saturation pulses to reduce signal coming from parts of the field-of-view that may be subjected to non-rigid motion during the acquisition of the magnetic resonance imaging dataset. This is advantageous for sagittal or coronal slice orientations (e.g., in head imaging), where the field-of-view typically covers body parts that are not of interest. It may also be advantageous to reduce the signal coming from the moving heart when imaging adjacent structures like the lungs.

According to an embodiment, the method includes estimating motion parameters for each set of additional k-space lines directly after they have been acquired, by comparing the respective additional k-space lines with the scout image; if the motion parameters for a set of k-space lines exceed a pre-determined threshold value, an operator is alerted or a re-acquisition of the echo train related to the set of additional k-space lines is triggered. The motion parameters may be rigid-body motion parameters, including, for example, three translational and three rotational parameters, or non-rigid motion parameters. The motion parameters may be estimated using the first act of the method described below for generating a motion-corrected magnetic resonance image dataset.

According to a further aspect, the present embodiments are also directed to a method for generating a motion-corrected magnetic resonance image dataset of an object, including receiving k-space data acquired using the acquisition method according to an embodiment, and receiving a low-resolution scout image dataset and sets of additional k-space lines acquired using the acquisition method according to an embodiment.

The motion correction algorithm includes, in a first act, estimating motion parameters for each set of additional k-space lines by minimizing the data consistency error between the additional k-space lines and a forward model using the low-resolution scout scan as an estimate for the image dataset. The forward model is described by an encoding matrix including the motion parameters to be estimated, Fourier encoding, and optionally subsampling and/or coil sensitivities of a multi-channel coil array. In a second act, the motion correction algorithm includes estimating the motion-corrected image dataset by minimizing the data consistency error between the k-space data acquired in the imaging protocol and a forward model described by an encoding matrix. The encoding matrix includes the motion parameters estimated in the first act for each set of additional k-space lines, Fourier encoding, and optionally subsampling and/or coil sensitivities of a multi-channel coil array.

The motion parameters may be rigid-body motion parameters, including, for example, three translational and three rotational parameters, or non-rigid motion parameters.

Thus, the minimization problem is carried out in two acts. In a first act, motion parameters are estimated for each set of guidance lines by minimizing the data consistency error of the forward model, which may amount to a comparison with the low-resolution scout image. In a second act, the motion-corrected image is estimated using the motion parameters estimated in the first step. Thereby, alternating repeated updates of the otherwise coupled optimization variables x (e.g., image vector) and 0 (e.g., motion parameters) is avoided. Rather, the rapid scout image dataset is used as an image estimate x. This leads to a highly efficient optimisation problem that is fully separable across the echo trains and does not require repeated updates of x, which may include millions of imaging voxels. The minimization problem may be derived from a SENSE parallel imaging forward model, as described in K. P. Pruessmann, M. Weiger, M. B. Scheidegger, and P. Boesiger, “SENSE: sensitivity encoding for fast MRI,” Magn. Reson. Med., vol. 42, no. 5, pp. 952-962, 1999, with rigid body motion parameters included (“SENSE+motion”). The overall method is described in Magn. Reson. Med. 2023:1-14, doi: 10.1002/mrm.29534, which is incorporated herein by reference.

In a further aspect of the present embodiments, a magnetic resonance imaging apparatus is provided, which includes a radio frequency controller configured to drive an RF-coil (e.g., including a multi-channel coil-array, a gradient controller configured to control gradient coils, and a control unit configured to control the radio frequency controller) and the gradient controller to execute the imaging protocol according to the invention. The MRI-apparatus may be a commercially available MRI-apparatus that has been programmed to perform the method of the present embodiments.

According to a further aspect of the present embodiments, a computer configured to generate a motion-corrected magnetic resonance image dataset is provided. The computer may be any computer including a sufficiently powerful processing unit that may be a CPU or GPU, or a number of such processing units. Accordingly, the computer may be a PC, a server, or a console of an MRI apparatus, but the computer also may be a computer that is remote from the MRI apparatus (e.g., may be connected with the MRI apparatus through the internet). Accordingly, the computer may also be a cloud computer, a remote server, etc. The computer may also be a mobile device, such as a laptop, tablet computer, or mobile phone.

According to a further aspect of the present embodiments, a computer program is provided. The computer program includes program code that causes a magnetic resonance imaging apparatus, such as the apparatus described herein, to execute the method of the present embodiments (e.g., the method for acquiring an MR image dataset). However, the program code may also encode the described method for generating a motion-corrected magnetic resonance image dataset, and the program code may run on a computer as described herein.

According to a further aspect, the present embodiments are directed to a non-transitory computer-readable medium containing a computer program as described herein. The computer-readable medium may be any digital storage medium, such as a hard disc, a cloud, an optical medium such as a CD or DVD, a memory card such as a compact flash, memory stick, a USB-stick, multimedia stick, secure digital memory card (SD), etc.

All features disclosed with regard to the acquisition method may be combined with all features of method for generating a motion-corrected MRI dataset and vice versa. Also, all features of the disclosed methods may be embodied in the MRI apparatus, computer program, and computer-readable storage medium according to other aspects of the invention and vice versa.

### BRIEF DESCRIPTION OF THE DRAWINGS

FIG. 1 is a schematic representation of an MRI apparatus according to an embodiment;

FIG. 2 is a schematic representation of a three-dimensional k-space;

FIG. 3 is a sequence diagram of an MRRAGE sequence with motion guidance lines;

FIG. 4 is a sequence diagram of a TSE sequence with motion guidance lines;

FIG. 5 is a sequence diagram of a TSE sequence with motion guidance lines according to an embodiment;

FIG. 6 is a sequence diagram of the scout acquisition according to an embodiment;

FIG. 7 is an illustration of an alternating optimization algorithm; and

FIG. 8 is an illustration of a SAMER optimization.

### DETAILED DESCRIPTION

Similar elements are designated with the same reference signs in the drawings.

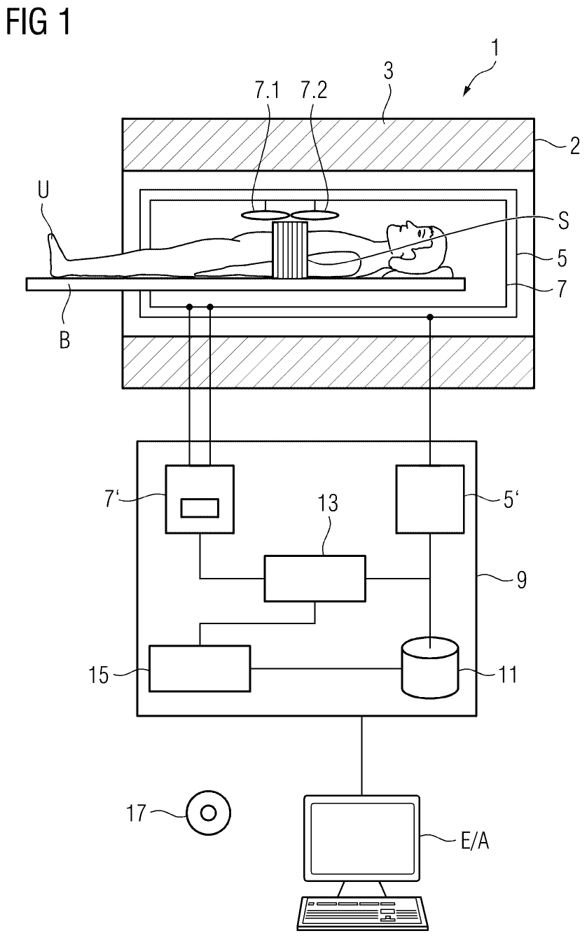

FIG. 1 schematically shows an embodiment of a magnetic resonance (MR) apparatus 1. The MR apparatus 1 has an MR data acquisition scanner 2 with a magnet 3 that generates a constant magnetic field, a gradient coil arrangement 5 that generates gradient fields, one or more radiofrequency (RF) antennas 7 for radiating and receiving RF signals, and a control computer 9 configured to perform an embodiment of a method. The radio-frequency antennas 7 may include a multi-channel coil array including at least two coils (e.g., the schematically shown coils 7.1 and 7.2) that may be configured to transmit and/or receive RF signals (e.g., MR signals).

In order to acquire MR data from an examination subject U (e.g., a patient or a phantom), the subject U is introduced on a bed B into the measurement volume of the scanner 2. MR data may be acquired using a method according to an embodiment from a stack S of 2D slices. The control computer 9 controls the MR apparatus 1, and the gradient coil arrangement 5 with a gradient controller 5′ and the RF antenna 7 with a RF transmit/receive controller 7′. The RF antenna 7 has multiple channels corresponding to the multiple coils 7.1, 7.2 of the coil arrays, in which signals may be transmitted or received. The control computer 9 also has an imaging protocol processor 15 that determines the imaging protocol, including a sampling order. A control unit 13 of the control computer 9 is configured to execute all the controls and computation operations required for acquisitions. Intermediate results and final results required for this purpose or determined in the process may be stored in a memory 11 of the control computer 9. A user may enter control commands and/or view displayed results (e.g., image data) via an input/output interface E/A. A non-transitory data storage medium 17 may be loaded into the control computer 9 and may be encoded with programming instructions (e.g., program code) that cause the control computer 9, and the various functional units thereof described above, to implement any or all embodiments of the method.

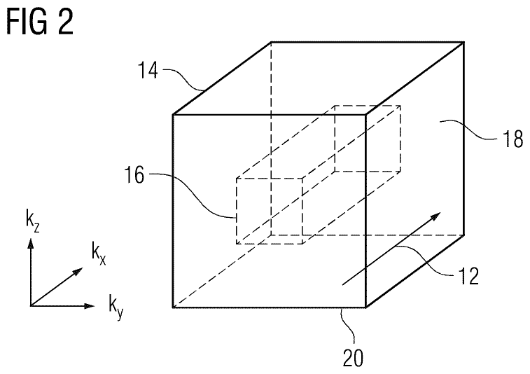

FIG. 2 illustrates a three-dimensional k-space 14 having dimension kₓ in frequency encoding (readout) direction, and k_{y} and k_{z} in the phase encode plane 20. A k-space line acquired during one echo is illustrated at 12. The k-space volume 14 includes a central region 16 and a periphery 18. The additional k-space lines as well as the k-space lines acquired for the low-resolution scout are located in the central region 16. In the phase encode plane 20, the central region 16 may cover about 1/12 to 1/16 in each direction (e.g., less than 1/100 of the total square phase encode plane 20).

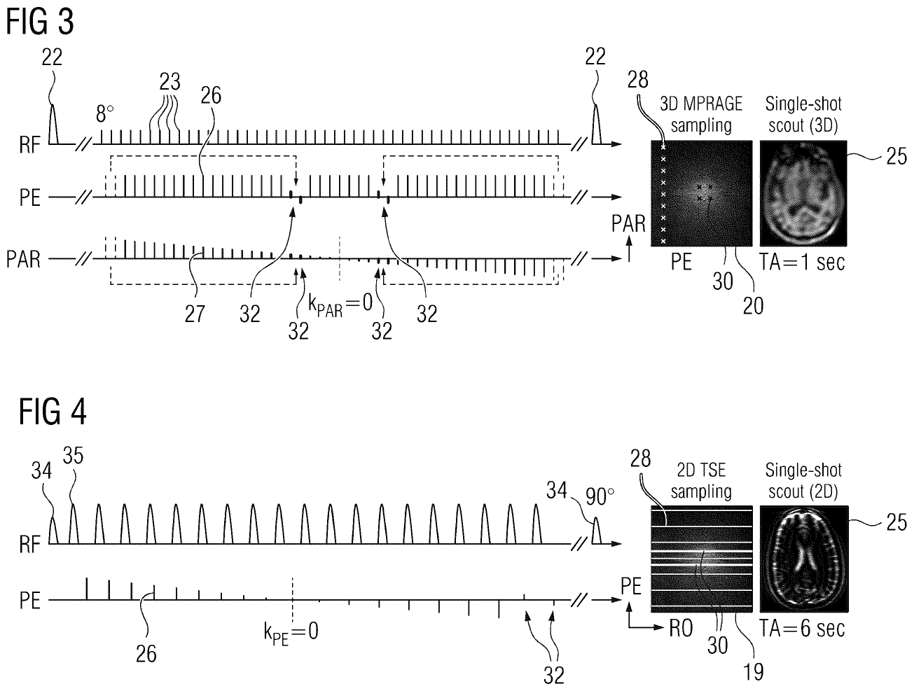

FIG. 3 illustrates a 3D MPRAGE sequence with motion guidance lines according to the prior art disclosed in Magn. Reson. Med 2023:1-14, doi: 10.1002/mrm.29534. On the left, a sequence diagram is shown indicating the RF pulses on the top, the phase encode (PE) gradients in the first direction are shown in the middle, and the phase encode gradients in the second direction (PAR for partition) are shown at the bottom. As usual for MPRAGE, an echo train starts with a 180° inversion pulse 22, followed by a wait time and then by a series of low flip angle (e.g., 8°) pulses 23, where a k-space line is acquired after each pulse 23. The ordering is linear, where after each readout, phase encode gradient blips 26, 27 are applied in the PE and PAR directions, so that the phase encode plane 20 is sampled in a straight line, as illustrated at 28. Each point 28 indicates k-space lines oriented perpendicular to the phase encode plane 20. Four echoes from the regular imaging protocol were removed from the echo train to accommodate four guidance lines 30 located near the center of k-space. The respective phase encode gradients are illustrated at 32. The corresponding 3D MPRAGE low-resolution scout image 25 is acquired in a single shot, which requires only an acquisition time TA of about 1 sec. If linear sampling is used, contrast of this particular linear sampling matches the contrast of the guidance lines, because the center of k-space is sampled at about a same wait time after the inversion pulse 22 for both the scout image and in the high-resolution image. However, this approach (e.g., exchanging some of the k-space lines from the regular imaging protocol with the guidance lines and sampling the scout image with the same type of imaging sequence) will not work for all types of imaging sequence and contrasts, as demonstrated by the next example.

FIG. 4 illustrates a T2-weighted 2D TSE sequence with motion guidance lines according to the prior art. The depicted echo train includes a 90° pulse 34 followed by a train of 180° refocusing pulses 35 that result in a train of spin-echoes. Since a 2D sequence is provided, only one phase encoding gradient PE is applied, and the depicted 3D k-space 19 has PE and RO dimensions (e.g., readout dimensions), so that one k-space line 28 is depicted not as a point, but as a line in this illustration 19. In this imaging protocol, standard distributed ordering is used, and two guidance lines 30, 32 are appended at the end of each echo train. The single-shot scout scan 25 (e.g., TA=6 seconds) matches the contrast of the guidance lines (e.g., here, heavily T2-weighted due to a long TE of approximately 200 ms). However, the acquisition time of 6 seconds is rather long; hence, the scout cannot be considered motion-free, which is a prerequisite for SAMER. This is an example where it is not advantageous to integrate the motion guidance lines into the echo train, and use the same type of imaging sequence for the scout and the high-resolution image dataset.

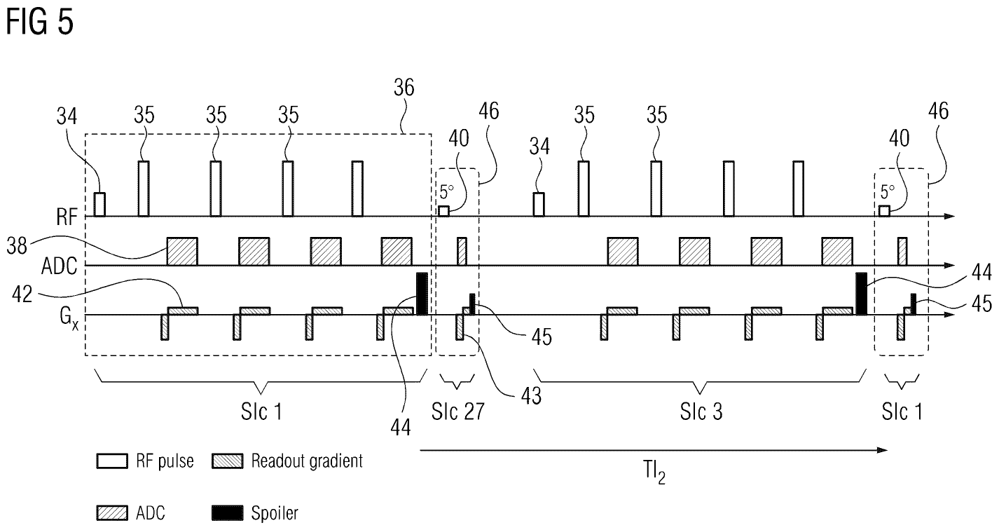

FIG. 5 illustrates a 2D TSE sequence according to an embodiment. For example, FIG. 5 demonstrates the implementation of FLASH guidance lines into a 2D TSE sequence, where a set of one or more flash guidance lines 46 are inserted after each TSE echo train 36. The sequence diagram depicts the RF pulses on the top, the readout windows 38 indicated as analogue-to-digital converter (ADC), and the readout gradient Gₓ on the bottom line. Two echo trains 36 are illustrated for different slices of the stack of 2D slices, the first for slice no. 1 and the second for slice no. 3. The RF pulses of each echo train 36 include a 90° pulse 34 followed by a train of 180° refocusing pulses 35. After each refocusing pulse 35, a k-space line is acquired during readout 38, using readout (e.g., frequency encoding) gradient 42.

After each TSE echo train 36, a gradient spoiler 44 is played in order to destroy and unwanted coherences. After the gradient spoiler 44, the second recovery time TI₂ begins and after the second recovery time TI₂ has elapsed, a set 46 of one or multiple guidance lines 30 are played on the same slice, each including a low-flip angle slice selective excitation pulse 40, spatial encoding gradients 43, and a gradient spoiler 45. In contrast to the prior art 2D TSE sequence illustrated in FIG. 4, the guidance lines are no longer part of the TSE echo train 36 but present a separate entity 46. A small RF flip angle (e.g., 5°) is used in the pulses 40 to minimize impact on the TSE imaging contrast. Further, the slice ordering of the guidance lines is permuted (e.g., the TSE echo train for slice no. 1 is followed by a set 46 of one or several guidance line for slice no. 27, and the TSE echo train for slice no. 3 is followed by a guidance line for slice no. 1). This permutation allows to use the recovery time TI₂ and thereby boosts the available signal in the guidance lines. In the example shown in FIG. 3, guidance lines for a specific slice are acquired a recovery time TI₂ after the corresponding TSE echo train, where TI₂ may be about 150-400 ms, 200-350 ms, or 240-290 ms (e.g., about 300 ms). In case of short TSE echo trains, the guidance lines for a given slice may be acquired N echo trains later in order to achieve a beneficial TI₂. Optionally, guidance lines are not acquired for every slice, but only a subset, if the temporal resolution is high enough. Besides T1 recovery, magnetization transfer effects also occur during TI₂. In this example, the acquisition and contrast of the motion guidance lines are completely decoupled from those of the imaging protocol, and the type of imaging sequences and sequence settings with which the motion guidance lines are acquired is different (e.g., FLASH vs. TSE).

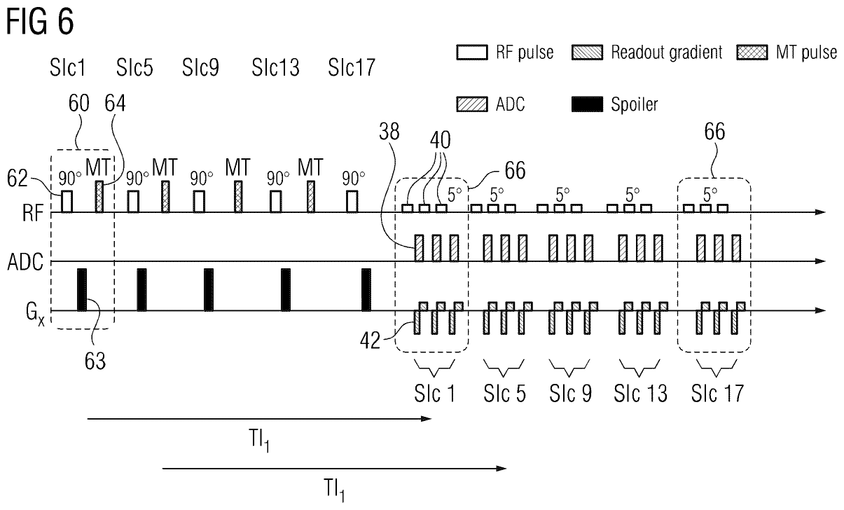

FIG. 6 demonstrates an example implementation of a low-resolution scout acquisition that is configured to match the contrast of the flash guidance lines used in the 2D TSE sequence illustrated in FIG. 5. The scout acquisition consists of saturation modules 60 for slice numbers 1, 5, 9, 13, 17. Each saturation module 60 includes a 90° RF pulse 62 followed by gradient spoiling 63, a recovery time TI₁, and a readout module 66. However, more complicated saturation techniques including multiple RF pulses and spoilers including flip angles deviating from 90° may be provided. The readout module 66 includes a small number (e.g., 2 to 18 or 4 to 8) of FLASH-type readouts including low-flip angle slice selective excitations 40, spatial encoding gradients, and spoiling (not shown). Spoiling may be used both for the flash guidance lines in the scout and the imaging protocol. The readout modules 66 of each slice are played a pre-determined first recovery time TI₁ after the saturation module 60 of the respective slice. A slice inter-leaving scheme is used to best exploit the recovery time TI₁ and improve scan efficiency (e.g., in this case, the saturation modules 60 for the 1^{st}, 5^{th}, 9^{th} 13^{th} and 17^{th} slice are first played consecutively, followed by readout modules 66 for the 1^{st}, 5^{th}, 9^{th} 13^{th} and 17^{th} slice). A slice ordering scheme that reduces overlap/crosstalk between the slices excited during one TI may be chosen.

In one embodiment, the second recovery time TI₂ of the guidance lines (see FIG. 5) is matched to the first recovery times TI₁ of the scout (FIG. 6), as otherwise, their contrast will differ. In this example, the recovery time TI₁ is also at least approximately 300 ms.

Additionally, magnetization transfer pulses MT may be included to better match the contrast of the flash guidance lines.

The scout and guidance lines approach of the present embodiments is independent of the desired TSE imaging contrast (e.g., the same acquisition module may be used across T1, T2 and FLAIR TSE). This is because each TSE echo train (e.g., T1, T2, FLAIR) will lead to the same spin state (e.g., negligible longitudinal magnetization), which may also be produced in the scout using a saturation module. Further, the FLASH guidance lines were designed to cause minimal disruption to the TSE sequence timing, which makes the FLASH guidance lines easy to integrate. The scout acquisition is very rapid (e.g., 1-2 sec) and may be played once before the imaging sequence. The data consistency-based motion estimation using the scout and guidance lines follows the approach disclosed in the articles by D. Polak et al. in Magn. Reason. cited herein. In vivo example reconstructions with instructed step motion have shown a significant improvement in image quality after retrospective motion correction.

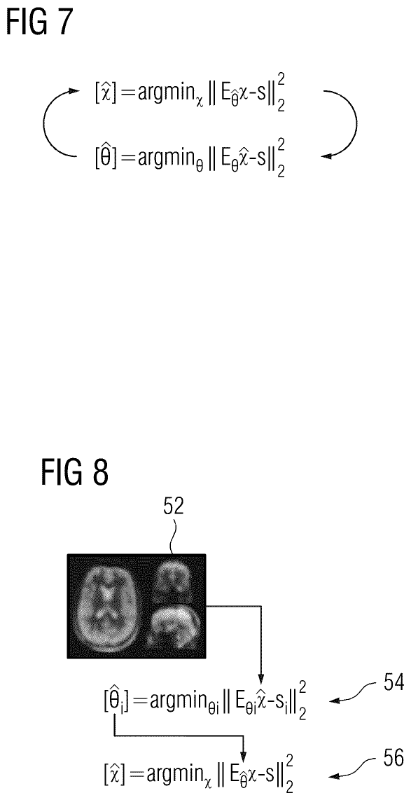

A retrospective motion correction technique that may be used on the MR signals acquired with the acquisition method of the present embodiments, and, for example, to estimate the motion states, will now be described with reference to FIGS. 7 and 8. The mathematical model used is an extension of SENSE parallel imaging, as described in the above-cited paper by K. P. Pruessmann et al., with rigid-body motion parameters included into the forward model.

The forward model or encoding operator E_{θ} for a given patient motion vector θ (e.g., including motion parameters over time) relates the motion-free image x to the acquired multi-channel k-space data s. At each time point i that is considered (e.g., the acquisition time of the sets of guidance lines), the position of the subject is described by a new set of six rigid-body motion parameters θᵢ that describe the 3D position of the object. Accordingly, the multi-channel k-space data sᵢ acquired at time point i may be related to the 3D image volume x through image rotations Rᵢ, image translations Tᵢ, coil sensitivity maps C, Fourier operator F, and under-sampling mask Mᵢ by the following formula 1

$${s}_{i} = {E}_{{θ}_{i}} x = {M}_{i} {FCT}_{{θ}_{i}} {R}_{{θ}_{i}} x \qquad [ 1 ]$$

In prior art methods, as illustrated in FIG. 7, both the motion corrected image vector x and the motion vector (trajectory) θ are estimated by performing an alternating, repeated optimization between the image vector (formula 2) and the motion vector (formula 3):

$$[ \hat{x} ] = arg {min}_{x} {‖ {E}_{\hat{θ}} x - s ‖}_{2} \qquad [ 2 ]$$

$$[ \hat{θ} ] = arg {min}_{θ} {‖ {E}_{θ} \hat{x} - s ‖}_{2} \qquad [ 3 ]$$

This may lead to convergence issues, as updates of x and θ will be computed on inaccurate information. Further, the reconstruction is computationally demanding, as repeated updates of x (e.g., millions of imaging voxels) are needed.

Using one or a number of ultra-fast low-resolution scout scans 52, the motion trajectory may be directly estimated, as illustrated in FIG. 8, thus avoiding the time-consuming alternate optimization. The scout image 52, designated by \tilde{x}, approximates the motion-free image volume \hat{x}, and each motion state may be determined independently by minimizing the data consistency error of the forward model 54:

$$[ {\hat{θ}}_{i} ] = arg {min}_{{θ}_{i}} {‖ {E}_{{θ}_{i}} \tilde{x} - {s}_{i} ‖}_{2} \qquad [ 4 ]$$

In the method of the present embodiments, the guidance lines are used instead of or in addition to the k-space data s in this first act of the optimization. In one embodiment, only the guidance lines are used.

For the final image reconstruction, the motion states/parameters from each set of guidance lines are combined, and the motion-mitigated image is obtained from solving a standard least-squares problem 56:

$$[ \hat{x} ] = arg {min}_{x} {‖ {E}_{\hat{θ}} x - s ‖}_{2} \qquad [ 5 ]$$

This strategy completely avoids the difficult non-linear and non-convex joint optimization that contains millions of unknowns, as the strategy only considers six rigid body parameters per motion optimization, and the strategy does not require computationally costly full or partial updates to the image.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for acquiring a magnetic resonance image dataset of a field-of-view including a body part of a subject, the method comprising:
using an imaging protocol in which spatial encoding is performed using phase encoding gradients along at least one phase encoding direction, and frequency encoding gradients along a frequency encoding direction, wherein k-space is sampled during the imaging protocol in a plurality of k-space lines oriented along the frequency encoding direction, and having different positions in the at least one phase encoding direction;
acquiring a low-resolution scout image dataset of the field-of-view; and
acquiring sets of one or more additional k-space lines within a central region of k-space at at least approximately regular intervals during the imaging protocol,
wherein a contrast of the low-resolution scout image dataset and a contrast of the sets of one or more additional k-space lines are at least approximately matched and are independent of a contrast of the magnetic resonance image dataset.

2. The method of claim 1, wherein the low-resolution scout image dataset and the sets of one or more additional k-space lines are acquired after an at least approximately matched magnetization preparation.

3. The method of claim 1, wherein the low-resolution scout image dataset and the sets of one or more additional k-space lines are acquired using low flip angle excitation pulses.

4. The method of claim 1, wherein the low-resolution scout image dataset is acquired using one or more saturation preparation modules that are configured such that the contrast of the low-resolution scout image dataset matches the contrast of the sets of one or more additional k-space lines, and
wherein each of the one or more saturation preparation module is followed by a readout of one or more k-space lines after a pre-determined first recovery time.

5. The method of claim 1, wherein the imaging protocol comprises a plurality of echo trains, one or more k-space lines being acquired in each echo train of the plurality of echo trains, and
wherein a set of additional k-space lines of the sets of additional k-space lines is acquired before or after at least some echo trains of the plurality of echo trains using low flip angle excitation pulses.

6. The method of claim 1, wherein k-space lines of the low-resolution scout image dataset are acquired a pre-determined first recovery time after a saturation preparation module, and
wherein the sets of one or more additional k-space lines are acquired a pre-determined second recovery time after an echo train, wherein the pre-determined first recovery time and pre-determined second recovery time are equal within ±20%, within ±10%, or within ±5%.

7. The method of claim 6, wherein the imaging protocol is a two-dimensional imaging protocol, in which a stack of two-dimensional slices is acquired.

8. The method of claim 7, wherein:
the additional k-space lines relating to one slice are acquired directly after an echo train in which k-space lines of another slice were acquired, such that the second recovery time is increased to a pre-determined value;
acquiring the low-resolution scout image dataset comprises playing saturation preparation modules relating to a plurality of slices, and then acquiring k-space lines of the plurality of slices after the pre-determined first recovery time; or
a combination thereof.

9. The method of claim 1, wherein the saturation preparation modules include magnetization transfer preparation pulses that are adapted to match the contrast of the low-resolution scout image dataset to the contrast of the one or more additional k-space lines.

10. The method of claim 1, wherein flow attenuation pulses applied outside of the field-of-view are used during the acquiring of the low-resolution scout image dataset.

11. The method of claim 1, wherein the imaging protocol includes regional saturation pulses to reduce signal coming from parts of the field-of-view that are subjectable to non-rigid motion during the acquiring of the magnetic resonance imaging dataset.

12. The method of claim 1, further comprising:
estimating motion parameters for each of the sets of one or more additional k-space lines directly after the sets of one or more additional k-space lines have been acquired, the estimating comprising comparing the respective additional k-space lines with the low-resolution scout image dataset; and
when the motion parameters for a set of additional k-space lines of the sets of one or more additional k-space lines exceed a pre-determined threshold value, alerting an operator or triggering a re-acquisition of the echo train related to the set of additional k-space lines.

13. A method for generating a motion-corrected magnetic resonance image dataset of an object, the method comprising:
receiving k-space data acquired using an acquisition method, the acquisition method being for acquiring a magnetic resonance image dataset of a field-of-view including a body part of a subject, the acquisition method comprising:
using an imaging protocol in which spatial encoding is performed using phase encoding gradients along at least one phase encoding direction, and frequency encoding gradients along a frequency encoding direction, wherein k-space is sampled during the imaging protocol in a plurality of k-space lines oriented along the frequency encoding direction, and having different positions in the at least one phase encoding direction;
acquiring a low-resolution scout image dataset of the field-of-view; and
acquiring sets of one or more additional k-space lines within a central region of k-space at at least approximately regular intervals during the imaging protocol, wherein a contrast of the low-resolution scout image dataset and a contrast of the one or more additional k-space lines are at least approximately matched and are independent of a contrast of the magnetic resonance image dataset;
receiving the low-resolution scout image dataset and the sets of one or more additional k-space lines acquired using the acquisition method;
estimating motion parameters for each of the sets of one or more additional k-space lines, the estimating of the motion parameters comprising minimizing a first data consistency error between the respective set of one or more additional k-space lines and a forward model using the low-resolution scout image dataset as an estimate for the magnetic resonance image dataset, wherein the forward model is described by a first encoding matrix including the motion parameters to be estimated and Fourier encoding; and
estimating the motion-corrected image dataset, the estimating of the motion-corrected image dataset comprising minimizing a second data consistency error between the k-space data acquired in the imaging protocol and a forward model described by a second encoding matrix, wherein the second encoding matrix includes the motion parameters estimated for each of the sets of one or more additional k-space lines and Fourier encoding.

14. The method of claim 13, wherein the first encoding matrix further includes subsampling, coil sensitivities of a multi-channel coil array, or a combination thereof.

15. The method of claim 13, wherein the second encoding matrix further includes subsampling, coil sensitivities of a multi-channel coil array, or a combination thereof.

16. A magnetic resonance imaging apparatus comprising:
a radio frequency (RF) controller configured to drive an RF-coil comprising a multi-channel coil array;
a gradient controller configured to control gradient coils; and
a control unit configured to control the radio frequency controller and the gradient controller to execute an imaging protocol,
wherein the control unit is configured to acquire a magnetic resonance image dataset of a field-of-view including a body part of a subject, the control unit being configured to acquire the magnetic resonance image dataset comprising the control unit being configured to:
use the imaging protocol in which spatial encoding is performed using phase encoding gradients along at least one phase encoding direction, and frequency encoding gradients along a frequency encoding direction, wherein k-space is sampled during the imaging protocol in a plurality of k-space lines oriented along the frequency encoding direction, and having different positions in the at least one phase encoding direction;
acquire a low-resolution scout image dataset of the field-of-view; and
acquire sets of one or more additional k-space lines within a central region of k-space at at least approximately regular intervals during the imaging protocol, wherein a contrast of the low-resolution scout image dataset and a contrast of the one or more additional k-space lines are at least approximately matched and are independent of a contrast of the magnetic resonance image dataset.
